(19) United States
(12) Patent Application Publication
(10) Pub. No.: US 2017/0047917 A1
(43) Pub. Date: Feb. 16, 2017

(54) SIGNAL DELAY CELLS

(71) Applicant: WASHINGTON STATE UNIVERSITY, Pullman, WA (US)

(72) Inventors: Deukhyoun HEO, Pullman, WA (US); Pawan AGARWAL, Pullman, WA (US)

(73) Assignee: WASHINGTON STATE UNIVERSITY, Pullman, WA (US)

(21) Appl. No.: 15/304,491

(22) PCT Filed: Apr. 16, 2014
(86) PCT No.: PCT/US2014/034393

§ 371 Date: Oct. 14, 2016

(51) Int. Cl. H03K 5/13; H03L 7/099; H03K 5/134

(52) U.S. Cl. CPC H03K 5/131; H03K 5/134; H03L 7/0992; H03K 2005/00071

(57) ABSTRACT

In some examples, a circuit is described. The circuit may be included in a digital phase-locked loop (PLL) and may include a first delay cell, a second delay cell, and a delay controller. The first delay cell may include a first inverter circuit that includes first and second transistors and may be configured to receive and to delay a first signal. The delay of the first inverter circuit may be based on first and second voltages respectively provided to the first and second transistors. The second delay cell may include a second inverter circuit that includes third and fourth transistors and may be configured to receive and to delay a second signal. The delay of the second inverter circuit may be based on third and fourth voltages respectively provided to the third and fourth transistors. The delay controller may be configured to provide the first, second, third, and fourth voltages.

### BACKGROUND

Unless otherwise indicated herein, the materials described herein are not prior art to the claims in the present application and are not admitted to be prior art by inclusion in this section.

Digital phase-locked loops (ADPLL) may be used in many applications that range from clock signal generation in microprocessors to frequency synthesis. In general, an ADPLL may include a digitally-controlled oscillator (DCO) that generates an output signal with a frequency that is locked onto a frequency of an input signal (a reference signal). To lock the frequency of the output signal with the frequency of the input signal, an ADPLL may include a time-to-digital converter (TDC) configured to compare a phase of the reference signal to a phase of the output signal generated by the oscillator, and to generate a digital output that is proportional or otherwise related to the phase difference between the phase of the input signal and the phase of the output signal. The digital output of the TDC may include a quantization error introduced by the TDC when the phase of the reference signal is compared to the phase of the output signal. Through the feedback of the output signal to the TDC, the ADPLL may drive the frequency of the output signal to the frequency of the input signal and may match the phase of the output signal with the phase of the input signal. An output phase noise of the output signal may be dependent on the quantization error introduced by the TDC.

### SUMMARY

Techniques described herein generally relate to signal delay cells.

In some examples, a circuit may include a first delay cell, a second delay cell, and a delay controller. The first delay cell may include a first inverter circuit that includes first and second transistors. The first delay cell may be configured to receive and to delay a first signal based on a first delay of the first inverter circuit and to output the delayed first signal. The first delay of the first inverter circuit may be based on first and second voltages respectively provided to the first and second transistors. The second delay cell may include a second inverter circuit that includes third and fourth transistors. The second delay cell may be configured to receive and to delay a second signal based on a second delay of the second inverter circuit and to output the delayed second signal. The second delay of the second inverter circuit may be based on third and fourth voltages respectively provided to the third and fourth transistors. The delay controller may be coupled to the first delay cell and the second delay cell. The delay controller may be configured to provide the first, second, third, and fourth voltages. The first, second, third, and fourth voltages may be configured such that the first delay is different in duration than the second delay.

In some examples, a circuit may include a first input terminal, a second input terminal, a delay unit, an arbiter circuit, and a delay controller. The first input terminal may be configured to receive a first signal and the second input terminal may be configured to receive a second signal. The delay unit may be coupled to the first and second input terminals. The delay unit may include a first delay cell and a second delay cell. The first delay cell may be configured to delay the first signal by a first delay based on a first set of voltages applied to a first set of transistors within the first delay cell. The second delay cell may be configured to delay the second signal by a second delay based on a second set of voltages applied to a second set of transistors within the second delay cell. The arbiter circuit may be coupled to the delay unit and may be configured to receive the delayed first and second signals. The arbiter may be further configured to output a signal indicative of which of the delayed first and second signals is received first by the arbiter circuit. The delay controller may be coupled to the delay unit. The delay controller may be configured to provide the first and second sets of voltages to the delay unit. The first and second sets of voltages may be configured such that the first delay is different in duration than the second delay.

In some examples, a circuit may include a digitally controlled oscillator circuit and a digital comparison unit. The digitally controlled oscillator circuit may be configured to generate an output signal based on a comparison signal. The digital comparison unit may be coupled to the digitally controlled oscillator circuit. The digital comparison unit may be configured to generate the comparison signal based on the output signal and a reference signal. The digital comparison unit may include multiple delay modules that each include a delay unit and an arbiter circuit. The delay unit of each delay module may be configured to receive first and second signals and to output delayed first and second signals. The first signal may be delayed by a first delay by a first delay cell based on a first set of voltages applied to a first set of transistors within the first delay cell. The second signal may be delayed by a second delay by a second delay cell based on a second set of voltages applied to a second set of transistors within the second delay cell. The arbiter circuit may be coupled to the delay unit and may be configured to output an arbitration signal based on the delayed first and second signals. The comparison signal may be based on the arbitration signals that is generated by each of the delay modules.

In some examples, a method may include delaying a first signal in a first delay cell for a first delay. The first delay may be based on first voltages provided to a first set of transistors in the first delay cell. The method may also include delaying a reference signal in a second delay cell for a second delay. The second delay may be based on second voltages provided to a second set of transistors in the second delay cell. The method may also include generating an arbitration signal based on which of the delayed first signal and the delayed reference signal is respectively output first by the first and second delay cells. Furthermore, the method may include generating a comparison signal based on the arbitration signal and generating an output signal based on the comparison signal, the first signal that is based on the output signal.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings. In the drawings:

FIG. 1A is a schematic diagram of an example circuit that includes a delay unit with first and second delay cells;

FIG. 1B is a schematic diagram of an example inverter circuit;

FIG. 2 is a schematic diagram of another example circuit that includes a delay module;

FIG. 3 is a block diagram of an example digital comparison unit;

FIG. 4 is a block diagram of an example ADPLL with a digital comparison unit;

FIG. 5 is a flow diagram of an example method; and

FIG. 6 is a block diagram illustrating an example computing device in which the circuit(s) and method(s) of FIGS. 1A, 1B, 2, 3, 4, and/or 5 may be implemented, all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. The aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatus/circuits, and systems, related to signal delay cells and in particular, but not exclusively, to signal delay cells used in all digital phase-locked loops (ADPLL).

Briefly stated, in some examples, a circuit is described. The circuit may be included in a digital phase-locked loop (PLL) and may include a first delay cell, a second delay cell, and a delay controller. The first delay cell may include a first inverter circuit that includes first and second transistors. The first delay cell may receive and may delay a first signal based on a first delay of the first inverter circuit and may output the delayed first signal. The first delay of the first inverter circuit may be based on first and second voltages respectively provided to the first and second transistors. The second delay cell may include a second inverter circuit that includes third and fourth transistors. The second delay cell may receive and may delay a second signal based on a second delay of the second inverter circuit and may output the delayed second signal. The second delay of the second inverter circuit may be based on third and fourth voltages respectively provided to the third and fourth transistors. The delay controller may be coupled to the first delay cell and the second delay cell. The delay controller may provide the first, second, third, and fourth voltages. The first, second, third, and fourth voltages may be configured such that the first delay is different in duration than the second delay.

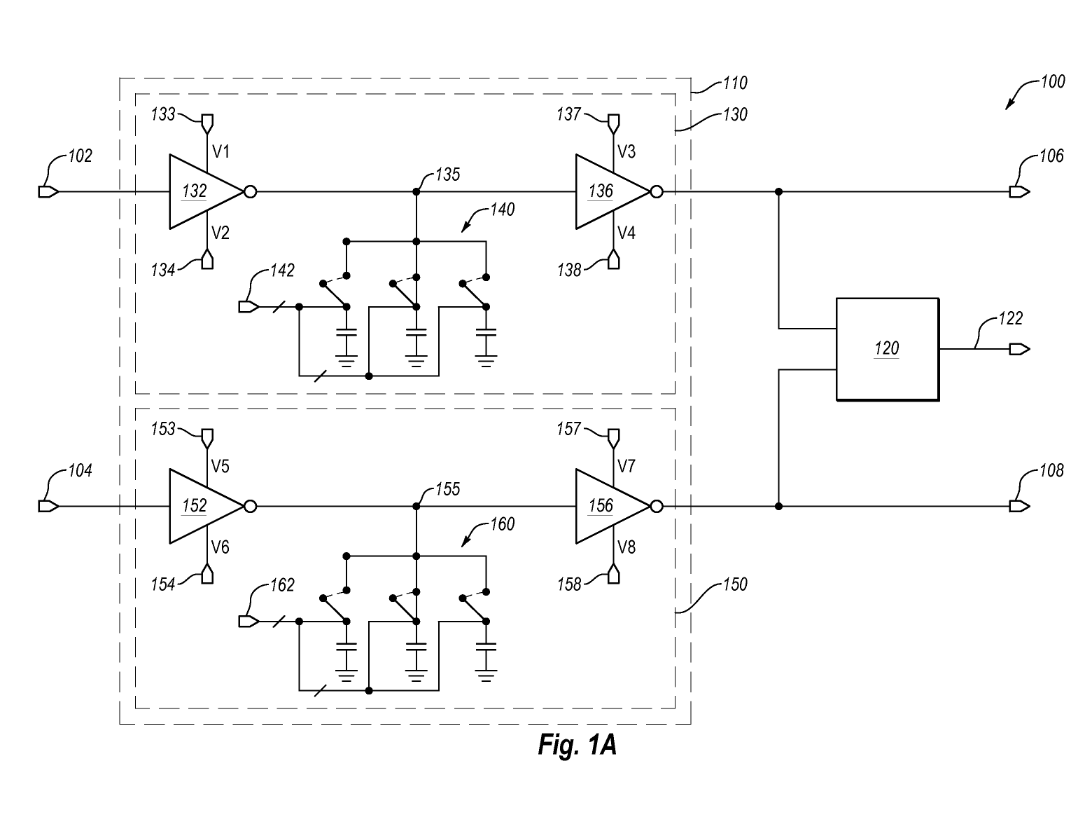

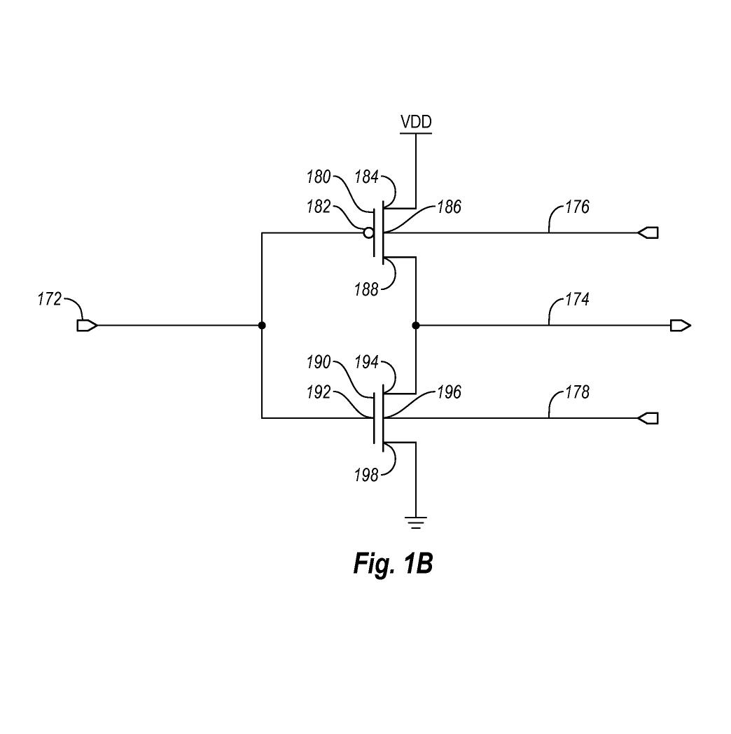

FIG. 1A is a schematic diagram of an example circuit 100 that includes a delay unit 110 with first and second delay cells 130 and 150, arranged in accordance with at least some embodiments described herein. The circuit 100 may include a first input terminal 102 configured to receive a first signal with a first phase. The circuit 100 may also include a second input terminal 104 configured to receive a second signal with a second phase. The circuit 100 may further include first and second output terminals 106 and 108 and an arbiter circuit 120 coupled to the first and second output terminals 106 and 108. The delay unit 110 may be coupled to the first and second input terminals 102 and 104, the first and second output terminals 106 and 108, and the arbiter circuit 120.

The first delay cell 130 may be coupled to the first input terminal 102 and the first output terminal 106. The first delay cell 130 may include a first inverter circuit 132 and a second inverter circuit 136. An input terminal of the first inverter circuit 132 may be coupled to the first input terminal 102 and an output terminal of the first inverter circuit 132 may be coupled to an input terminal of the second inverter circuit 136. An output terminal of the second inverter circuit 136 may be coupled to the first output terminal 106.

The first delay cell 130 may receive a signal from the first input terminal 102 and may provide a delayed version of the signal on the first output terminal 106. The delay of the first delay cell 130 may be based at least in part on delays of the first and second inverter circuits 132 and 136 as described below.

The first inverter circuit 132 may include a voltage terminal 133 and a voltage terminal 134. The voltage terminal 133 may receive a voltage v1 and the voltage terminal 134 may receive a voltage v2. Based on the voltages v1 and v2 respectively received at the voltage terminals 133 and 134, a delay of the first inverter circuit 132 may be determined. In some embodiments, the voltages v1 and v2 respectively provided to the voltage terminals 133 and 134 may be adjustable to adjust the delay of the first inverter circuit 132. According to various embodiments, the voltages v1 and v2 may be provided by/from a delay controller, a processor, or some other circuit/system configured to provide voltages to the first inverter circuit 132 to adjust the delay of the first inverter circuit 132.

The second inverter circuit 136 may include a voltage terminal 137 and a voltage terminal 138. The voltage terminal 137 may receive a voltage v3 and the voltage terminal 138 may receive a voltage v4. Based on the voltages v3 and v4 respectively received at the voltage terminals 137 and 138, a delay of the second inverter circuit 136 may be determined. In some embodiments, the voltages v3 and v4 respectively provided to the voltage terminals 137 and 138 may be adjustable to adjust the delay of the second inverter circuit 136. According to various embodiments, the voltages v3 and v4 may be provided by/from a delay controller, a processor, or some other circuit/system configured to provide voltages to the second inverter circuit 136 to adjust the delay of the second inverter circuit 136.

The delay of the first delay cell 130 may be a combination of the delay of the first inverter circuit 132 and the delay of the second inverter circuit 136. Thus, to adjust the delay of the first delay cell 130, the delay of the first inverter circuit 132 and/or the delay of the second inverter circuit 136 may be adjusted. In some embodiments, the voltages v1 and v3 and the voltages v2 and v4 may be the same. In these and other embodiments, the delays of the first and second inverter circuits 132 and 136 may be approximately equal or equal. In some embodiments, the voltages v1-v4 may each be different and may be adjusted independently. In these and other embodiments, the delays of the first and second inverter circuits 132 and 136 may be approximately equal or equal or different based on the values for the voltages v1-v4. In some embodiments, the voltages v1 and v2 may be complementary such that an increase in the voltage v1 is accompanied by a decrease in the voltage v2. Alternately or additionally, the voltages v3 and v4 may be complementary such that an increase in the voltage v3 is accompanied by a decrease in the voltage v4. A further description of the complementary nature of the voltages provided to an inverter circuit in a delay cell is provided with respect to FIG. 1B.

In some embodiments, the first delay cell 130 may further include a capacitor bank circuit 140 coupled to a first node 135 that couples the output terminal of the first inverter circuit 132 and the input terminal of the second inverter circuit 136. The capacitor bank circuit 140 may include multiple capacitors. Each of the capacitors may be coupled to the first node 135 by a switch such that the capacitor bank circuit 140 may include multiple switches. The capacitor bank circuit 140 may open and close the switches to switch one or more of the multiple capacitors into or out of electrical connection with the first node 135 based on a control signal received at a control signal terminal 142 that is coupled to the switches. The increased capacitance at the first node 135 that occurs in response to the closure of one or more of the switches may increase the delay of the first inverter circuit 132, and thus increase the delay of the first delay cell 130.

The second delay cell 150 may be coupled to the second input terminal 104 and the second output terminal 108. The second delay cell 150 may include a first inverter circuit 152 and a second inverter circuit 156. An input terminal of the first inverter circuit 152 may be coupled to the second input terminal 104 and an output terminal of the first inverter circuit 152 may be coupled to an input terminal of the second inverter circuit 156. An output terminal of the second inverter circuit 156 may be coupled to the second output terminal 108.

The second delay cell 150 may receive a signal from the second input terminal 104 and may provide a delayed version of the signal on the second output terminal 108. The delay of the second delay cell 150 may be based at least in part on the delays of the first and second inverter circuits 152 and 156 as described below.

The first inverter circuit 152 may include a voltage terminal 153 and a voltage terminal 154. The voltage terminal 153 may receive a voltage v5 and the voltage terminal 154 may receive a voltage v6. Based on the voltages v5 and v6 respectively received at the voltage terminals 153 and 154, a delay of the first inverter circuit 152 may be determined. In some embodiments, the voltages v5 and v6 respectively provided to the voltage terminals 153 and 154 may be adjustable to adjust the delay of the first inverter circuit 152. According to various embodiments, the voltages v5 and v6 may be provided by/from a delay controller, a processor, or some other circuit/system configured to provide voltages to the first inverter circuit 152 to adjust the delay of the first inverter circuit 152.

The second inverter circuit 156 may include a voltage terminal 157 and a voltage terminal 158. The voltage terminal 157 may receive a voltage v7 and the voltage terminal 158 may receive a voltage v8. Based on the voltages v7 and v8 respectively received at the voltage terminals 157 and 158, a delay of the second inverter circuit 156 may be determined. In some embodiments, the voltages v7 and v8 respectively provided to the voltage terminals 157 and 158 may be adjustable to adjust the delay of the second inverter circuit 156. According to various embodiments, the voltages v7 and v8 may be provided by/from a delay controller, a processor, or some other circuit/system configured to provide voltages to the second inverter circuit 156 to adjust the delay of the second inverter circuit 156.

The delay of the second delay cell 150 may include a combination of the delay of the first inverter circuit 152 and the delay of the second inverter circuit 156. Thus, to adjust the delay of the second delay cell 150, the delay of the first inverter circuit 152 and/or the delay of the second inverter circuit 156 may be adjusted. In some embodiments, the voltages v5 and v6 and the voltages v7 and v8 may be the same. In these and other embodiments, the delays of the first and second inverter circuits 152 and 156 may be approximately equal or equal. In some embodiments, the voltages v5-v8 may each be different and may be adjusted independently. In these and other embodiments, the delays of the first and second inverter circuits 152 and 156 may be approximately equal or equal or different based on the values for the voltages v5-v8. In some embodiments, the voltages v5 and v6 may be complementary such that an increase in the voltage v5 is accompanied by a decrease in the voltage v6. Alternately or additionally, the voltages v7 and v8 may be complementary such that an increase in the voltage v7 is accompanied by a decrease in the voltage v8. A further description of the complementary nature of the voltages provided to an inverter circuit in a delay cell is provided with respect to FIG. 1B.

In some embodiments, the second delay cell 150 may further include a capacitor bank circuit 160 coupled to a second node 155 that couples the output terminal of the first inverter circuit 152 and the input terminal of the second inverter circuit 156. The capacitor bank circuit 160 may include multiple capacitors. Each of the capacitors may be coupled to the second node 155 by a switch such that the capacitor bank circuit 160 may include multiple switches. The capacitor bank circuit 160 may open and close the switches to switch one or more of the multiple capacitors into or out of electrical connection with the second node 155 based on a control signal received at a control signal terminal 162 that is coupled to the switches. The increased capacitance at the second node 155 that occurs in response to the closure of one or more of the switches may increase the delay of the first inverter circuit 152, and thus increase the delay of the second delay cell 150.

In some embodiments, the delays of each of the inverter circuits 132, 136, 152, and 156 of the first and second delay cells 130 and 150 may be adjustable by the use of the voltages v1 through v8 over a dynamic delay range of at least 8× where an approximately linear relationship is maintained between the voltages v1 through v8 and the delays of the inverter circuits 132, 136, 152, and 156. For example, if the first inverter circuit 132 includes a dynamic delay range of 8× and is able to generate a delay of 2 picoseconds, the first inverter circuit 132 may also able to generate a delay of 16 picoseconds. In some embodiments, the capacitor bank circuits 140 and 160 may extend the dynamic delay ranges of the first inverter circuits 132 and 152. In some embodiments, when the dynamic delay range of the first inverter circuits 132 and 152 are sufficient for a particular application, the capacitor bank circuits 140 and 160 may not be used. In these and other embodiments, when the capacitor bank circuits 140 and 160 are not included, the capacitance at the output terminals of the first inverter circuits 132 and 152 may be reduced and may thereby reduce a power consumption of the circuit 100.

In some embodiments, a range of delays of a single inverter circuit, such as each of the first and second inverter circuits 132, 136, 152, and 156, may range between approximately 50 femtoseconds and 100 picoseconds or some other range. In these and other embodiments, the delay of the first and second delay cells 130 and 150 may range between approximately 100 femtoseconds and 200 picoseconds or some other range.

In some embodiments, the adjustment to the voltages v1-v8 that are provided to the inverter circuits 132, 136, 152, and 156 may include stepwise adjustments. In these and other embodiments, the delays of the inverter circuits 132, 136, 152, and 156 may be stepwise adjustable. Alternately or additionally, the voltages v1-v8 correspondingly provided to the inverter circuits 132, 136, 152, and 156 may be continuously adjusted or otherwise changed over time. In these and other embodiments, the delays of the inverter circuits 132, 136, 152, and 156 may be continuously adjusted or otherwise changed over time.

The delay unit 110 may delay a first signal with the first delay cell 130 and may delay a second signal with the second delay cell 150. In some embodiments, the delay of the first delay cell 130 may be the same or different than the delay of the second delay cell 150. For example, in some embodiments, the delay of the first delay cell 130 and the delay of the second delay cell 150 may be adjusted in a stepwise manner. In these and other embodiments, a smallest difference between the delay of the first delay cell 130 and the delay of the second delay cell 150 may be based on the delay difference between the steps of the delay adjustments of the first and second delay cells 130 and 150. The smallest delay difference between the steps of the delay adjustment of the first and second delay cells 130 and 150 may be referred to herein as a resolution of the delay unit 110.

The delayed first signal and the delayed second signal may be provided to the arbiter circuit 120. The arbiter circuit 120 may provide an output signal on an output terminal 122 that is based on which of the first and second delayed signals is first received by the arbiter circuit 120. Any configuration of the arbiter circuit 120 that provides the above-described functionality and features may be used herein. For example, the arbiter circuit 120 may include a flip-flop circuit or some other type of circuit.

The output signal of the arbiter circuit 120 may help to determine a delay difference, e.g., a phase difference, between the first and second signals. For example, assume that a first signal lags a second signal by 2 picoseconds, such that a rising edge of the first signal rises 2 picoseconds after a rising edge of the second signal. The first signal may be provided to the first delay cell 130 that includes a delay of 0.5 picoseconds. The second signal may be provided to the second delay cell 150 that includes a delay of 5 picoseconds. Thus, the delay between the first and second delay cells 130 and 150 may be 4.50 picoseconds. As a result, the rising edge of the delayed first signal output by the first delay cell 130 may lead the rising edge of the delayed second signal output by the second delay cell 150 by 2.5 picoseconds. The arbiter circuit 120 may thus receive a rising edge of the first delayed cell before the rising edge of the second delayed signal is received. The output signal of the arbiter circuit 120 may indicate that the delayed first signal leads the delayed second signal. As a result, it may be determined that the first signal, when received by the delay unit 110, either leads the second signal or lags the second signal by less than the delay difference between the first and second delay cells, e.g., 5 picoseconds. Thus, the circuit 100 may be used to obtain information about a delay difference between the first and second signals.

Additionally, the delays between the first and second delay cells 130 and 150 may be adjusted to refine the information about the delay difference between the first and second signals. Continuing with the above example, assume that the delay of the second delay cell 150 is adjusted to be 3 picoseconds such that the delay between the first and second delay cells may be 2.5 picoseconds. As a result, the delayed first signal may lead the delayed second signal when received by the arbiter circuit 120. With this configuration, it may be determined that the first signal, when received by the delay unit 110, leads the second signal or lags the second signal by less than the delay difference between the first and second delay cells, or 2.5 picoseconds in this example. Furthermore, assume that the delay of the second delay cell 150 is again adjusted to be 2 picoseconds such that the delay between the first and second delay cells may be 1.5 picoseconds. As a result, the delayed first signal may still lag the delayed second signal when received by the arbiter circuit 120. With this configuration and the previous information, it may be determined that the first signal, when received by the delay unit 110, lags the second signal by a delay between 1.5 picoseconds and 2.5 picoseconds.

Modifications, additions, or omissions may be made to FIG. 1A without departing from the scope of the present disclosure. For example, in some embodiments, the first delay cell 130 may include another capacitor bank circuit coupled to the output terminal of the second inverter circuit 136. The capacitance of the capacitor bank circuit coupled to the output terminal of the second inverter circuit 136 may adjust the delay of the second inverter circuit 136. Alternately or additionally, the first delay cell 130 may not include the capacitor bank circuit 140.

As another example, in some embodiments, the second delay cell 150 may include another capacitor bank circuit coupled to the output terminal of the second inverter circuit 156. The capacitance of the capacitor bank circuit coupled to the output terminal of the second inverter circuit 156 may adjust the delay of the second inverter circuit 156. Alternately or additionally, the second delay cell 150 may not include the capacitor bank circuit 160.

As another example, in some embodiments, the first delay cell 130 may not include the second inverter circuit 136. In these and other embodiments, the delay of the first delay cell 130 may be based on the delay of the first inverter circuit 132. Alternately or additionally, the second delay cell 150 may not include the second inverter circuit 156. In these and other embodiments, the delay of the second delay cell 150 may be based on the delay of the first inverter circuit 152. Alternately or additionally, the first and second delay cells 130 and 150 may include more than two inverter circuits. In some embodiments, the first and second delay cells 130 and 150 may include an even number of inverter circuits to avoid inverting signals when the signals are output by the first and second delay cells 130 and 150. Other configurations are possible.

FIG. 1B is a schematic diagram of an example inverter circuit 170, arranged in accordance with at least some embodiments described herein. The inverter circuit 170 may be an example of one of the first and second inverter circuits 132 and 136 of the first delay cell 130 and/or an example of one of the first and second inverter circuits 152 and 156 of the second delay cell 150 of FIG. 1A.

The inverter circuit 170 may include an input terminal 172, an output terminal 174, a first transistor 180, and a second transistor 190. The first transistor 180 may include a p-type transistor and may include a gate terminal 182, a source terminal 184, a base terminal 186, and a drain terminal 188. The second transistor 190 may include an n-type transistor and may include a gate terminal 192, a drain terminal 194, a base terminal 196, and a source terminal 198.

The gate terminals 182 and 192 of the first and second transistors 180 and 190 may be coupled to the input terminal 172. The drain terminals 188 and 194 of the first and second transistors 180 and 190 may be coupled to each other and to the output terminal 174. The source terminal 184 of the first transistor 180 may be coupled to a voltage such as VDD and the source terminal 198 of the second transistor 190 may be coupled to ground. The base terminal 186 of the first transistor 180 may be coupled to a first voltage terminal 176 and the base terminal 196 of the second transistor 190 may be coupled to a second voltage terminal 178.

In some embodiments, the input terminal 172 of the inverter circuit 170 may be analogous to the input terminals of the inverter circuits 132, 136, 152, and 156 of FIG. 1A, the output terminal 174 of the inverter circuit 170 may be analogous to the output terminals of the inverter circuits 132, 136, 152, and 156 of FIG. 1A, the first voltage terminal 176 may be analogous to the voltage terminals 133, 137, 153, and 157, and the second voltage terminal may be analogous to the voltage terminals 134, 138, 154, and 158.

A delay of the inverter circuit 170 between the input terminal 172 and the output terminal 174 may be based on threshold voltages of the first and second transistors 180 and 190. In particular, as the threshold voltages of the first and second transistors 180 and 190 decrease, the delay of the inverter circuit 170 may decrease.

To adjust the threshold voltage of the first transistor 180, a voltage applied to the base terminal 186 of the first transistor 180 by way of the first voltage terminal 176 may be adjusted. To adjust the threshold voltage of the second transistor 190, a voltage applied to the base terminal 196 of the second transistor 190 by way of the second voltage terminal 178 may be adjusted. As a result, the delay of the inverter circuit 170 may be based on first and second voltages respectively applied to the first and second voltage terminals 176 and 178. According to various embodiments, the first and second voltages may be provided by/from a delay controller, a processor, or some other circuit/system that may provide voltages.

A maximum threshold voltage of the first transistor 180, because it is a p-type transistor, may be achieved by a voltage at the base terminal 186 that is at VDD, for example. To decrease the threshold voltage and thereby decrease the delay of the first transistor 180, the voltage at the base terminal 186 may be decreased from VDD, for example.

A maximum threshold voltage of the second transistor 190, because it is an n-type transistor, may be achieved by a voltage at the base terminal 196 that is at ground potential, for example. To decrease the threshold voltage and thereby decrease the delay of the second transistor 190, the voltage at the base terminal 196 may be increased from ground potential, for example.

To maintain symmetry in the inverter circuit 170 such that rising and falling edges of signals that pass through the inverter circuit 170 include similar delays, an amount that the voltage at the base terminal 196 of the second transistor 190 is increased from ground potential may be equal or approximately equal to an amount that the voltage at the base terminal 186 of the first transistor 180 is decreased from VDD, for example. As a result, the voltages applied to the base terminals 186 and 196 of the first and second transistors 180 and 190 may be complementary such that an increase in the voltage applied to the base terminal 196 of the second transistor 190 may be approximately equal or equal to a decrease applied to the base terminal 186 of the first transistor 180. Thus, to decrease the delay of the inverter circuit 170, the voltage applied to the base terminal 196 of the second transistor 190 may be increased while the voltage applied to the base terminal 186 of the first transistor 180 may be decreased. To increase the delay of the inverter circuit 170, the voltage applied to the base terminal 196 of the second transistor 190 may be decreased while the voltage applied to the base terminal 186 of the first transistor 180 may be increased. An adjustment of the voltages applied to the base terminals 186 and 196 of the first and second transistors 180 and 190 as discussed herein may not appreciably affect the power consumption of the inverter circuit 170. For example, an adjustment to the voltages applied to the base terminals 186 and 196 of the first and second transistors 180 and 190 as discussed herein may affect the power consumption of the inverter circuit 170 by less than ten percent.

The first and second transistors 180 and 190 may include complementary metal-oxide-semiconductor (CMOS) or bipolar junction transistors (BJT) among other type of transistors, or some combination thereof. The above description references the gate terminal, drain terminal, source terminal, and base terminal of various transistors. The above description uses the nomenclature gate, drain, source, and base generically to represent different terminals of a transistor. The use of the names gate, drain, source, and base, although typically applied to CMOS transistors, may be used herein to generically describe the terminals of any type of transistor, such as a CMOS transistor. In some cases, the base terminal of a transistor may be referred to as a bulk (substrate) terminal of a transistor or as a second gate terminal of a transistor.

Modifications, additions, or omissions may be made to FIG. 1B without departing from the scope of the present disclosure. For example, in some embodiments, the inverter circuit 170 may include one or more other passive or active circuit components.

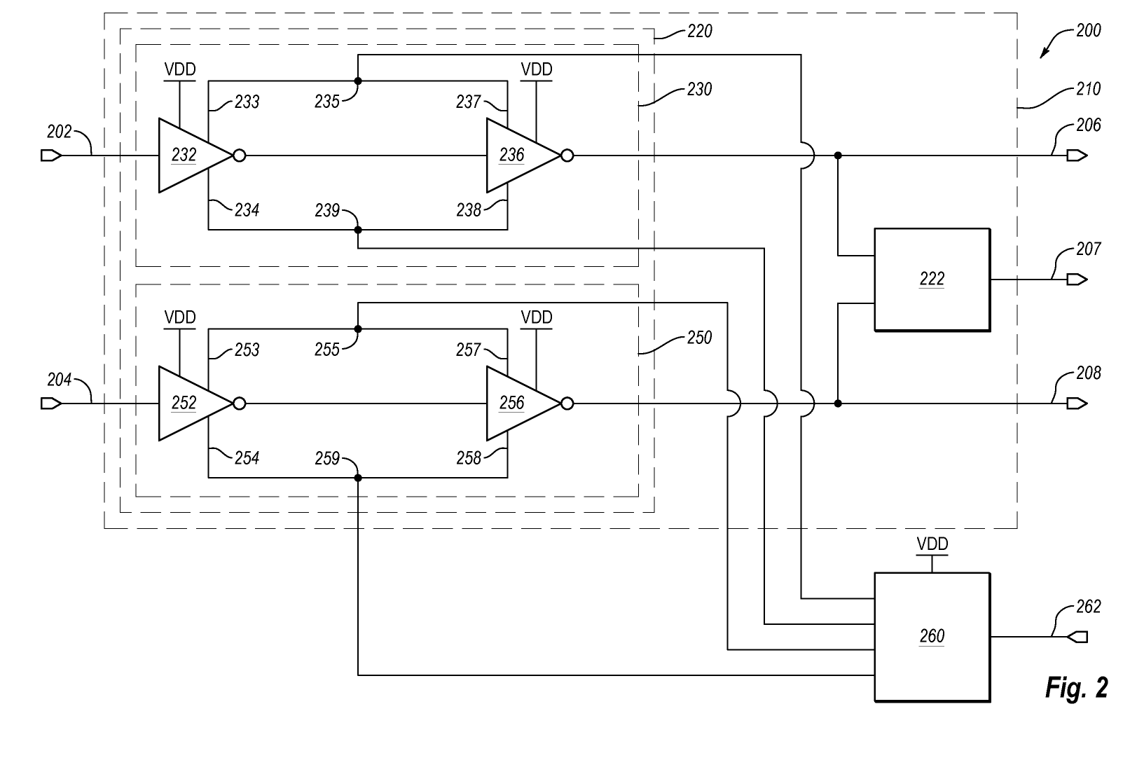

FIG. 2 is a schematic diagram of another example circuit 200 that includes a delay module 210, arranged in accordance with at least some embodiments described herein. The delay module 210 may include first and second input terminals 202 and 204 that are coupled to a delay unit 220 and first and second output terminals 206 and 208 that are coupled to the delay unit 220. The delay module 210 may also include an arbiter circuit 222 that is coupled to the first and second output terminals 206 and 208. The delay module 210 may receive a first signal on the first input terminal 202, delay the first signal with the delay unit 220, and output the delayed first signal on the first output terminal 206. The delay module 210 may receive a second signal on the second input terminal 204, delay the second signal with the delay unit 220, and output the delayed second signal on the second output terminal 208. The delay module 210 may also output a signal on an arbitration terminal 207 that indicates which of the delayed first and second signals are output first by the delay unit 220. In some embodiments, the delay module 210 may operate in a manner analogous to the circuit 100 of FIG. 1A.

As illustrated, the delay unit 220 may include a first delay cell 230 and a second delay cell 250. The first delay cell 230 may include a first inverter circuit 232 with voltage terminals 233 and 234 and a second inverter circuit 236 with voltage terminals 237 and 238. The operation of the first delay cell 230 may be analogous to the operation of the first delay cell 130 of FIG. 1A.

In the illustrated embodiment, the voltage terminals 233 and 237 of the respective first and second inverter circuits 232 and 236 may be electrically coupled at a voltage node 235. The voltage terminals 234 and 238 of the respective first and second inverter circuits 232 and 236 may be electrically coupled at a voltage node 239. In these and other embodiments, the voltage node 235 may be electrically coupled to base terminals of p-type transistors in the first and second inverter circuits 232 and 236. The voltage node 239 may be electrically coupled to base terminals of n-type transistors in the first and second inverter circuits 232 and 236.

The second delay cell 250 may include a first inverter circuit 252 with voltage terminals 253 and 254 and a second inverter circuit 256 with voltage terminals 257 and 258. The operation of the second delay cell 250 may be analogous to the operation of the second delay cell 150 of FIG. 1A.

In the illustrated embodiment, the voltage terminals 253 and 257 of the respective first and second inverter circuits 252 and 256 may be electrically coupled at a voltage node 255. The voltage terminals 254 and 258 of the respective first and second inverter circuits 252 and 256 may be electrically coupled at a voltage node 259. In these and other embodiments, the voltage node 255 may be electrically coupled to base terminals of p-type transistors in the first and second inverter circuits 252 and 256. The voltage node 259 may be electrically coupled to base terminals of n-type transistors in the first and second inverter circuits 252 and 256.

The circuit 200 may further include a delay controller 260 that is coupled to the first and second delay cells 230 and 250. The delay controller 260 may provide voltages to the voltage nodes 235, 239, 255, and 259 to adjust the delays of the first and second delay cells 230 and 250. The delay controller 260 may provide the voltages based on a voltage, such as VDD, coupled to the delay controller 260. In some embodiments, the delay controller 260 may receive a delay control signal on a signal terminal 262. According to various embodiments, the delay control signal may be provided by/from a processor, a control unit, or some other circuit/system configured to control the delay of the delay module 210.

The delay control signal may indicate the delays for the first and second delay cells 230 and 250. In these and other embodiments, the delay controller 260 may determine the voltages to provide to the voltage nodes 235, 239, 255, and 259 to cause the delays for the first and second delay cells 230 and 250 as indicated in the delay control signal.

In some embodiments, the delay controller 260 may include one or more digital-to-analog converters (DAC). In these and other embodiments, the delay control signal may include a digital signal that represents a voltage to provide to one of the voltage nodes 235, 239, 255, and 259. The DAC may convert the digital signal to an analog signal, e.g., a voltage, which is provided to one of the voltage nodes 235, 239, 255, and 259. In some embodiments, the DAC may receive a delay control signal for each of the voltage nodes 235, 239, 255, and 259 and may convert each of the delay control signals to the voltages for their corresponding voltage nodes 235, 239, 255, and 259.

In some embodiments, the resolution of the DAC in the delay controller 260 may determine a resolution of delay differences between the first and second delay cells 230 and 250. For example, when the DAC includes a resolution of 5 millivolts per bit, then the smallest voltage difference between the voltages applied to the first and second delay cells 230 and 250 may be 5 millivolts. As a result, a smallest delay difference between the first and second delay cells 230 and 250 may be a delay difference that results from a 5-millivolt change in the voltages at the voltage nodes 235, 239, 255, and 259. For example, in some embodiments, the smallest delay difference between the first and second delay cells 230 and 250 may be less than 1 picosecond, such as 130 femtoseconds or some other delay. In some embodiments, the difference in delay between the first and second delay cells 230 and 250 may range between 100 femtoseconds and 50 picoseconds.

In some embodiments, the delay controller 260 may include first and second complementary DACs. The first complementary DAC may provide voltages to the voltage nodes 235 and 239 of the first delay cell 230. The second complementary DAC may provide voltages to the voltage nodes 255 and 259 of the second delay cell 250. A complementary DAC may output two voltages that are complementary based on a single digital delay control signal. For example, the complementary DAC may output a first voltage as indicated by a first digital delay control signal and a second voltage that is equal to a source voltage, such as VDD that is provided to the complementary DAC, minus the first voltage. The source voltage VDD provided to the complementary DAC may be approximately equal or equal to the source voltage provided to each of the inverter circuits 232, 236, 252, and 256. In some embodiments, the complementary DAC may include a resistive ladder complementary DAC.

Modifications, additions, or omissions may be made to FIG. 2 without departing from the scope of the present disclosure. For example, in some embodiments, each of the voltage terminals 233, 234, 237, 238, 253, 254, 257, and 258 may be independently coupled to the delay controller 260. In these and other embodiments, the delay controller 260 may provide the same or different voltages to each of the voltage terminals 233, 234, 237, 238, 253, 254, 257, and 258. In this manner, each of the inverter circuits 232, 236, 252, and 256 may include similar or different delays. In these and other embodiments, the delay controller 260 may include four complementary DACs that are each configured to provide voltages to one of the inverter circuits 232, 236, 252, and 256.

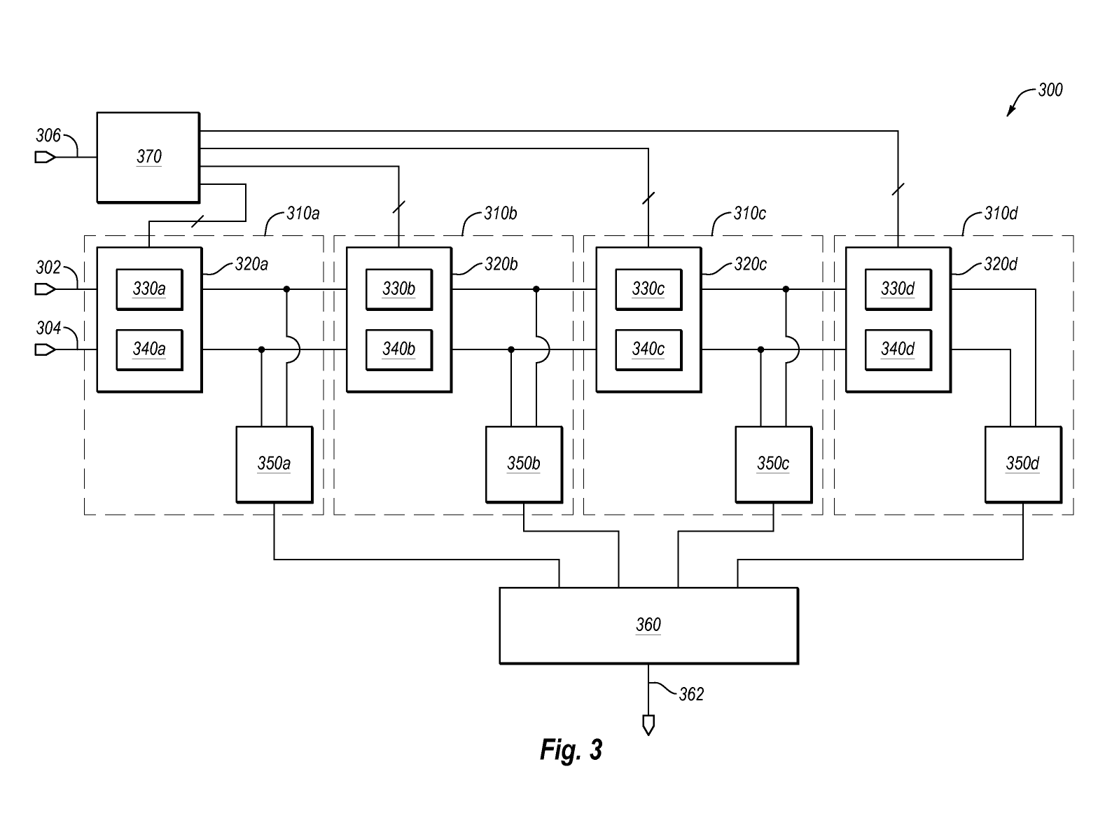

FIG. 3 is a block diagram of an example digital comparison unit 300, arranged in accordance with at least some embodiments described herein. The digital comparison unit 300 may include first, second, third, and fourth delay modules 310a, 310b, 310c, and 310d, which may be referred to herein collectively or individually as the delay module(s) 310. The digital comparison unit 300 may also include first and second input terminals 302 and 304, a delay control signal terminal 306, a comparison signal terminal 362, a combination unit 360 that is coupled to each of the delay modules 310 and the comparison signal terminal 362, and a delay controller 370 that is coupled to each of the delay modules 310 and the delay control signal terminal 306.

The first delay module 310a may be coupled to the first and second input terminals 302 and 304. The second delay module 310b may be coupled to the first delay module 310a, the third delay module 310c may be coupled to the second delay module 310b, and the fourth delay module 310d may be coupled to the third delay module 310c.

The first delay module 310a may include a delay unit 320a that is coupled to an arbiter circuit 350a. The delay unit 320a may include first and second delay cells 330a and 340a.

The second delay module 310b may include a delay unit 320b that is coupled to an arbiter circuit 350b. The delay unit 320b may include first and second delay cells 330b and 340b.

The third delay module 310c may include a delay unit 320c that is coupled to an arbiter circuit 350c. The delay unit 320c may include first and second delay cells 330c and 340c.

The fourth delay module 310d may include a delay unit 320d that is coupled to an arbiter circuit 350d. The delay unit 320d may include first and second delay cells 330d and 340d.

The delay units 320a, 320b, 320c, and 320d may be referred to herein as the delay unit(s) 320. The first delay cells 330a, 330b, 330c, and 330d may be referred to herein as the first delay cell(s) 330. The second delay cells 340a, 340b, 340c, and 340d may be referred to herein as the second delay cell(s) 340. The arbiter circuits 350a, 350b, 350c, and 350d may be referred to herein as the arbiter circuit(s) 350.

The delay modules 310 may operate in and/or may be configured in an analogous manner as the delay module 210 of FIG. 2 and thus no further description is provided herein of the delay modules 310.

The delay controller 370 may be analogous to the delay controller 260 of FIG. 2 and may provide voltages to each of the delay modules 310 to control the delay of each of the delay modules 310. In particular, the delay controller 370 may provide two sets of voltages to each of the delay modules 310. One of the sets of voltages may be provided to the first delay cells 330 to establish a first delay in the first delay cells 330 of the delay modules 310. The other set of voltages may be provided to the second delay cells 340 to establish a second delay in the second delay cells 340 of the delay modules 310. The delay controller 370 may set the voltages provided to each of the delay modules 310 based on a delay control signal received on a delay control signal terminal 306. According to various embodiments, the delay control signal may be provided by/from a processor, a control unit, or some other circuit/system configured to control the delays of the delay modules 310 in the digital comparison unit 300.

In some embodiments, the differences between the first and second delays in the respective first and second delay cells 330 and 340 of the delay modules 310 may be the same or different for each of the delay modules 310.

Arbitration signals output by each of the arbiter circuits 350 in the delay modules 310 may be provided to the combination unit 360. The combination unit 360 may combine the arbitration signals from each of the arbiter circuits 350 to form a comparison signal that may be output on the comparison signal terminal 362 of the digital comparison unit 300. The comparison signal may indicate a delay difference, such as a phase difference, between first and second signals respectively received on the first and second input terminals 302 and 304.

In some embodiments, the digital comparison unit 300 may include a thermometer to binary encoder. In these and other embodiments, the arbitration signals received from the arbiter circuits 350 may be in unary code or thermometer code. The digital comparison unit 300 may convert the unary code arbitration signals into the comparison signal that is in a binary format. Alternately or additionally, the digital comparison unit 300 may group the arbitration signals and the grouped arbitration signals may be output as the comparison signal.

The resolution of the comparison signal may be based on the number of delay modules 310 within the digital comparison unit 300 and the difference in delays of the first and second delay cells 330 and 340 in each of the delay modules 310. For example, the number of bits of the comparison signal may depend on the number of delay modules 310, where each of the delay modules 310 provides one unary bit for the comparison signal. The difference in delay of the first and second delay cells 330 and 340 may determine an amount of the delay difference indicated by a change in one value of the comparison signal or a quantization error of the comparison signal.

Furthermore, the number of delay modules 310 and the difference in delay of the first and second delay cells 330 and 340 may contribute to the range of frequencies for which the digital comparison unit 300 may provide granular information about the comparison between first and second signals received at the first and second input terminals 302 and 304. In particular, when one of the first and second delay cells 330 and 340 in each of the delay modules 310 includes the longest delay, the digital comparison unit 300 may indicate in which of N+1 delay ranges a delay difference between first and second signals may be found, where N is the number of delay modules 310 in the digital comparison unit 300. The size of the individual N+1 delay ranges may be based on the differences in delay between the first and second delay cells 330 and 340 in each of the delay modules 310.

For example, with one delay module 310, where X seconds is the difference in delay between the first and second delay cells 330 and 340 in the delay module 310 and the first delay cell 330 includes a longer delay, the comparison signal may indicate whether a first signal a) leads the second signal by more than X seconds, or b) leads the second signal by less than X seconds or lags the second signal. As another example, the digital comparison unit 300 may include two delay modules 310. A first of the two delay modules 310 may include a delay difference of X between the first and second delay cells 330 and 340 included therein. A second of the two delay modules 310 may include a delay difference of Y between the first and second delay cells 330 and 340 included therein. In these and other embodiments, when the first signal is delayed more than the second signal through the two delay modules 310, the comparison signal may indicate whether a first signal a) leads the second signal by more than X+Y seconds, b) leads the second signal by more than X seconds and less than X+Y seconds, or c) leads the second signal by less than X seconds or lags the second signal.

In some embodiments, the digital comparison unit 300 may indicate the delay difference between first and second signals with a discrete resolution based on the number of delay modules 310 in the digital comparison unit 300 and on the difference in delay in the first and second delay cells 330 and 340 in each of the delay modules 310.

Modifications, additions, or omissions may be made to FIG. 3 without departing from the scope of the present disclosure. For example, in some embodiments, the digital comparison unit 300 may include more or fewer than four delay modules 310. Alternately or additionally, the digital comparison unit 300 may include more than one delay controller 370. For example, in some embodiments, each of the delay modules 310 may include a delay controller.

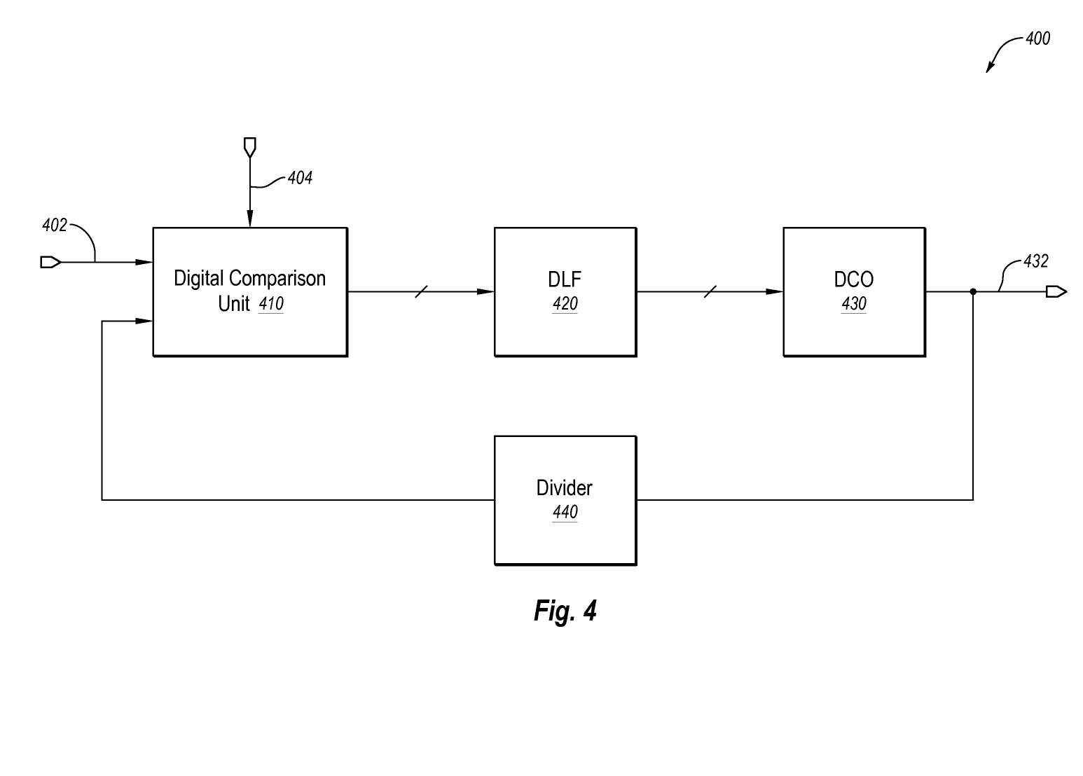

FIG. 4 is a block diagram of an example ADPLL 400 with a digital comparison unit 410, arranged in accordance with at least some embodiments described herein. The ADPLL 400 may also include a reference signal terminal 402, a control signal terminal 404, a digital loop filter (DLF) 420, a digitally controlled oscillator (DCO) 430, an output terminal 432, and a divider 440.

The reference signal terminal 402 and the control signal terminal 404 may be coupled to the digital comparison unit 410. The DLF 420 may include an input terminal coupled to an output terminal of the digital comparison unit 410 and an output terminal coupled to an input terminal of the DCO 430. The DCO 430 may be coupled to the output terminal 432 and an input terminal of the divider 440. The output terminal of the divider 440 may be coupled to the digital comparison unit 410. The digital comparison unit 410 may be analogous to the digital comparison unit 300 of FIG. 3 in general operation. Alternately or additionally, the digital comparison unit 410 may include identical and/or analogous components as the digital comparison unit 300 of FIG. 3.

The DCO 430 may generate an output signal with a frequency that is synchronized, e.g., locked, with a frequency of a reference signal received on the reference signal terminal 402. To synchronize the frequency of the output signal with the frequency of the reference signal, the digital comparison unit 410 may compare the phase of the reference signal to the phase of the divided output signal as divided by the divider 440. The digital comparison unit 410 may generate a comparison signal based on the phase difference between the phase of the reference signal and the phase of the output signal. The DLF may filter the comparison signal and provide the filtered comparison signal to the DCO 430. The DCO 430 may adjust the phase of the output signal until the ADPLL drives the frequency of the output signal to synchronize with the frequency of the reference signal.

The comparison signal generated by the digital comparison unit 410 may indicate a delay difference between the phases of the reference signal and the divided output signal. The delay difference, however, may be quantized based on the resolution of the digital comparison unit 410 and thus may include a quantization error. For example, when a difference in between the phases of the divided output signal and the reference signal is 6 picoseconds and the resolution of the digital comparison unit 410 is 4 picoseconds, the comparison signal may include a quantization error of 2 picoseconds. The quantization error of the comparison signal may increase the in-band phase noise of the ADPLL 400.

To reduce the quantization error of the comparison signal, the resolution of the digital comparison unit 410 may be adjusted based on a control signal received by the digital comparison unit 410 on the control signal terminal 404. According to various embodiments, the control signal may be provided by/from a processor, a control unit, or some other circuit/system configured to control the resolution of the digital comparison unit 410.

In some embodiments, the control signal may indicate a change in the voltages applied to transistors within delay cells of the delay modules of the digital comparison unit 410 to change the delay of the delay cells. When the delay of the delay cells is reduced, the resolution of the digital comparison unit 410 may be reduced. A reduction in the resolution may result in a reduction of the quantization error of the comparison signal and thus a reduction in the in-band phase noise of the ADPLL 400. A reduction in in-band phase noise of the ADPLL 400 may result in less phase noise and jitter in the output signal.

Furthermore, in some embodiments, when the output signal is synchronized with the reference signal, it may be advantageous to increase the resolution of the digital comparison unit 410 to enable the ADPLL 400 to more quickly synchronize the phases of the output signal with the phase of the reference signal. In these and other embodiments, the delays between the delay cells in the delay modules of the digital comparison unit 410 may be adjusted to be larger based on the control signal.

As the phases of the output signal and the reference signal become more synchronized, e.g., the delay difference between the output signal and the reference signal is reduced, the digital comparison unit 410 may adjust the delay of the delay cells in the delay modules based on the control signal to reduce the quantization error. As a result, the digital comparison unit 410 may facilitate a reduced synchronization time, e.g., lock time, of the ADPLL 400 and may facilitate a reduced in-band phase noise of the ADPLL 400 upon or during synchronization the phases of the output signal and the reference signal.

Modifications, additions, or omissions may be made to FIG. 4 without departing from the scope of the present disclosure. For example, in some embodiments, the ADPLL 400 may not include the divider 440.

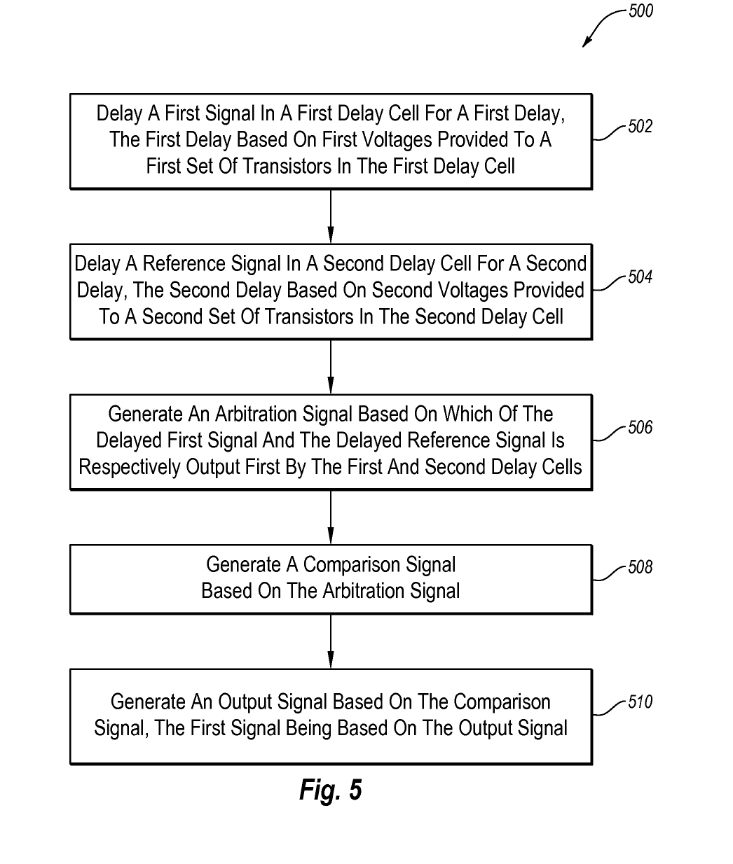

FIG. 5 illustrates an example flow diagram of a method 500, arranged in accordance with at least some embodiments described herein. The method 500 may be performed in whole or in part by, e.g., the circuit 100 of FIG. 1A, the inverter circuit 170 of FIG. 1B, the circuit 200 of FIG. 2, the digital comparison unit 300 of FIG. 3, the ADPLL 400 of FIG. 4, and/or variation(s) thereof. The method 500 includes various operations, functions, or actions as illustrated by one or more of blocks 502, 504, 506, 508, and/or 510. The method 500 may begin at block 502.

In block 502 [Delay A First Signal In A First Delay Cell For A First Delay, The First Delay Based On First Voltages Provided To A First Set Of Transistors In The First Delay Cell], a first signal in a first delay cell may be delayed for a first delay. The first delay may be based on first voltages provided to a first set of transistors in the first delay cell. In some embodiments, the first set of voltages in the first cell may include a first voltage and a second voltage. The first voltage and the second voltage may each be independently applied to one transistor of the first set of transistors. In some embodiments, the first voltage and the second voltage may be complementary such that an increase in the first voltage is accompanied by a decrease in the second voltage. Block 502 may be followed by block 504.

In block 504 [Delay A Reference Signal In A Second Delay Cell For A Second Delay, The Second Delay Based On Second Voltages Provided To A Second Set Of Transistors In The Second Delay Cell], a reference signal in a second delay cell may be delayed for a second delay. The second delay may be based on second voltages provided to a second set of transistors in the second delay cell. In some embodiments, the first delay may be different in duration than the second delay. Block 504 may be followed by block 506.

In block 506 [Generate An Arbitration Signal Based On Which Of The Delayed First Signal And The Delayed Reference Signal Is Respectively Output First By The First And Second Delay Cells], an arbitration signal may be generated based on which of the delayed first signal and the delayed reference signal is respectively output first by the first and second delay cells. Block 506 may be followed by block 508.

In block 508 [Generate A Comparison Signal Based On The Arbitration Signal], a comparison signal may be generated based on the arbitration signal. Block 508 may be followed by block 510.

In block 510 [Generate An Output Signal Based On The Comparison Signal, The First Signal Being Based On The Output Signal], an output signal may be generated based on the comparison signal and the first signal may be based on the output signal.

For this and other processes and methods disclosed herein, the functions performed in the processes and methods may be implemented in differing order. Furthermore, the outlined acts and operations are only provided as examples, and some of the acts and operations may be optional, combined into fewer acts and operations, or expanded into or supplemented with additional acts and operations without detracting from the essence of the disclosed embodiments.

For example, the method 500 may further include additionally delaying the delayed first signal in a third delay cell for a third delay. The third delay may be based on third voltages provided to a third set of transistors in the third delay cell. Alternately or additionally, the method 500 may further include additionally delaying the delayed reference signal in a fourth delay cell for a fourth delay, the fourth delay based on fourth voltages provided to a fourth set of transistors in the fourth delay cell. Alternately or additionally, the method 500 may further include generating a second arbitration signal based on which of the delayed first signal and the additionally delayed reference signal is respectively output first by the third and fourth delay cells. In these and other embodiments, the comparison signal may be based on the arbitration signal generated in block 506 and the second arbitration signal.

As another example, the method 500 may further include adjusting the first set of voltages and/or the second set of voltages to respectively adjust the first delay and/or the second delay.

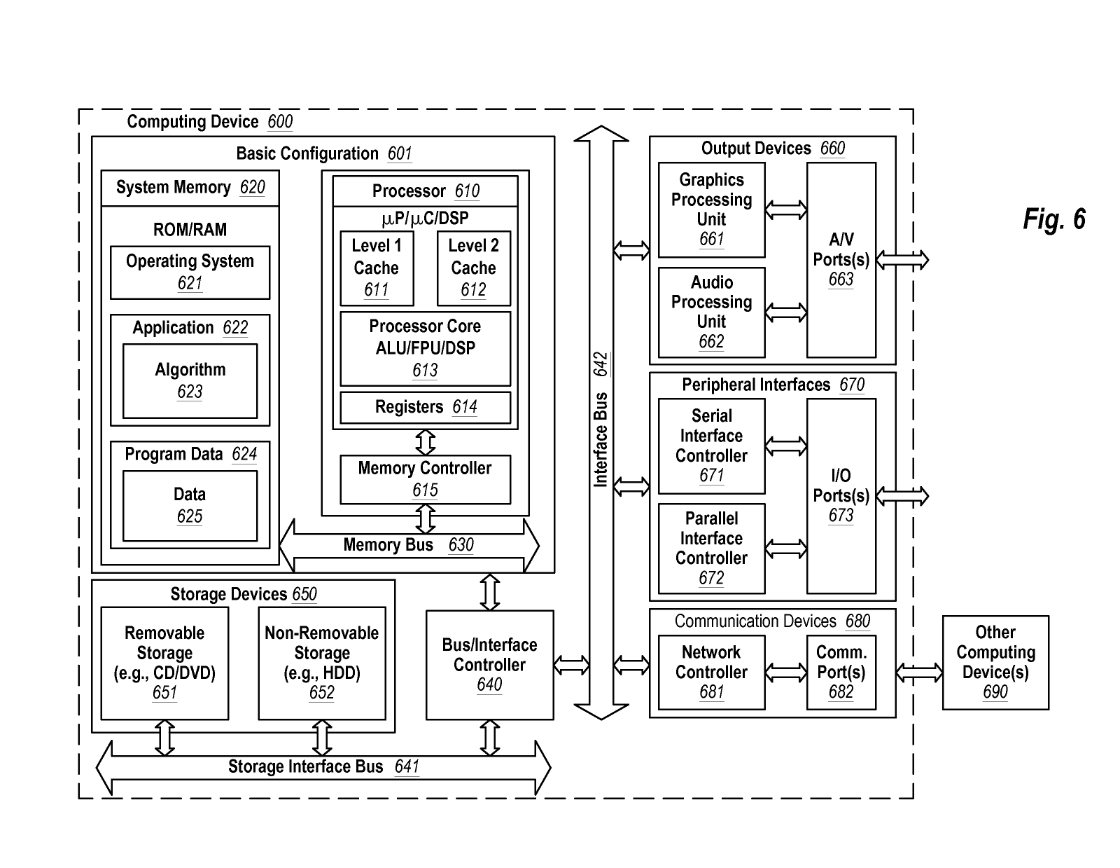

FIG. 6 is a block diagram illustrating an example computing device 600 in which the circuit(s) and method(s) in accordance with the present disclosure may be implemented. In a very basic configuration 601, the computing device 600 typically includes one or more processors 610 and a system memory 620. A memory bus 630 can be used for communicating between the processor 610 and the system memory 620.

Depending on the desired configuration, the processor 610 can be of any type including but not limited to a microprocessor (μP), a microcontroller (μC), a digital signal processor (DSP), or any combination thereof. The processor 610 can include one more levels of caching, such as a level one cache 611 and a level two cache 612, a processor core 613, and registers 614. The processor core 613 can include an arithmetic logic unit (ALU), a floating point unit (FPU), a digital signal processing core (DSP Core), or any combination thereof. In some embodiments, the processor 610 may implement the various signal delay cell related circuit(s) and method(s) described above. For example, the processor 610 may implement the various signal delay cell related circuit(s) and method(s) described above in an ADPLL for a clock distribution system within the processor 610. A memory controller 615 can also be used with the processor 610, or in some implementations the memory controller 615 can be an internal part of the processor 610.

Depending on the desired configuration, the system memory 620 can be of any type including, but not limited to, volatile memory (such as RAM), non-volatile memory (such as ROM, flash memory, etc.) or any combination thereof. In some embodiments, the system memory 620 may implement the various signal delay cell related circuit(s) and method(s) described above. For example, the system memory 620 may implement the various signal delay cell related circuit(s) and method(s) described above in an ADPLL for a clock distribution system within the system memory 620. The system memory 620 typically includes an operating system 621, one or more applications 622, and program data 624. The application 622 may include an algorithm 623. The program data 624 includes data 625 that is usable in connection with execution of the algorithm 623. In some embodiments, the application 622 can be arranged to operate with the program data 624 on the operating system 621.

The computing device 600 can have additional features or functionality, and additional interfaces to facilitate communications between the basic configuration 601 and any required devices and interfaces. For example, a bus/interface controller 640 can be used to facilitate communications between the basic configuration 601 and one or more data storage devices 650 via a storage interface bus 641. The data storage devices 650 may be removable storage devices 651, non-removable storage devices 652, or a combination thereof. Examples of removable storage and non-removable storage devices include magnetic disk devices such as flexible disk drives and hard-disk drives (HDDs), optical disk drives such as compact disk (CD) drives or digital versatile disk (DVD) drives, solid state drives (SSDs), and tape drives to name a few. Example computer storage media can include volatile and nonvolatile, removable and non-removable media implemented in any method or technology for storage of information, such as computer-readable instructions, data structures, program modules, or other data.

The system memory 620, the removable storage devices 651 and the non-removable storage devices 652 are all examples of computer storage media. Computer storage media includes, but is not limited to, RAM, ROM, EEPROM, flash memory or other memory technology, CD-ROM, digital versatile disks (DVDs) or other optical storage, magnetic cassettes, magnetic tape, magnetic disk storage or other magnetic storage devices, or any other medium which can be used to store the desired information and which can be accessed by the computing device 600. Any such computer storage media can be part of the computing device 600.

The computing device 600 can also include an interface bus 642 for facilitating communication from various interface devices (e.g., output interfaces, peripheral interfaces, and communication interfaces) to the basic configuration 601 via the bus/interface controller 640. Example output devices 660 include a graphics processing unit 661 and an audio processing unit 662, which can be configured to communicate to various external devices such as a display or speakers via one or more A/V ports 663. Example peripheral interfaces 670 include a serial interface controller 671 or a parallel interface controller 672, which can be configured to communicate with external devices such as input devices (e.g., keyboard, mouse, pen, voice input device, touch input device, etc.) or other peripheral devices (e.g., printer, scanner, etc.) via one or more I/O ports 673. An example communication device 680 includes a network controller 681, which can be arranged to facilitate communications with one or more other computing devices 690 over a network communication via one or more communication ports 682. The communication device 680 of one embodiment may implement the various signal delay cell related circuit(s) and method(s) described above. For example, the communication device 680 may include an optical port that may implement the various delay-cell related circuit(s) and method(s) described above in an ADPLL in a clock and data recovery circuit. Alternatively or additionally, the various delay-cell related circuit(s) and method(s) described above may be implemented elsewhere in the computing device 600.

The communication connection is one example of a communication media. Communication media may typically be embodied by computer-readable instructions, data structures, program modules, or other data in a modulated data signal, such as a carrier wave or other transport mechanism, and includes any information delivery media. A “modulated data signal” can be a signal that includes one or more of its characteristics set or changed in such a manner as to encode information in the signal. By way of example, and not limitation, communication media can include wired media such as a wired network or direct-wired connection, and wireless media such as acoustic, radio frequency (RF), infrared (IR), and other wireless media. The term computer-readable media as used herein can include both storage media and communication media.

The computing device 600 can be implemented as a portion of a small-form factor portable (or mobile) electronic device such as a cell phone, a personal data assistant (PDA), a personal media player device, a wireless web-watch device, a personal headset device, an application-specific device, or a hybrid device that includes any of the above functions. The computing device 600 can also be implemented as a personal computer including both laptop computer and non-laptop computer configurations.

The present disclosure is not to be limited in terms of the particular embodiments described herein, which are intended as illustrations of various aspects. Many modifications and variations can be made without departing from its spirit and scope. Functionally equivalent methods and apparatuses within the scope of the disclosure, in addition to those enumerated herein, are possible from the foregoing descriptions. Such modifications and variations are intended to fall within the scope of the appended claims. The present disclosure is to be limited only by the terms of the appended claims, along with the full scope of equivalents to which such claims are entitled. The present disclosure is not limited to particular methods, reagents, compounds compositions, or biological systems, which can, of course, vary. The terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible sub ranges and combinations of sub ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into sub ranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, various embodiments of the present disclosure have been described herein for purposes of illustration, and various modifications may be made without departing from the scope and spirit of the present disclosure. Accordingly, the various embodiments disclosed herein are not intended to be limiting, with the true scope and spirit being indicated by the following claims.

1. A circuit, comprising:
a first delay cell that includes a first inverter circuit, wherein the first inverter circuit includes first and second transistors, the first delay cell is configured to receive and to delay a first signal based on a first delay of the first inverter circuit and to output the delayed first signal, and the first delay of the first inverter circuit is based on first and second voltages respectively provided to the first and second transistors, wherein the first and second voltages are different;
a second delay cell that includes a second inverter circuit, wherein the second inverter circuit includes third and fourth transistors, the second delay cell is configured to receive and to delay a second signal based on a second delay of the second inverter circuit and to output the delayed second signal, and the second delay of the second inverter circuit is based on third and fourth voltages respectively provided to the third and fourth transistors, wherein the third and fourth voltages are different; and
a delay controller coupled to the first delay cell and the second delay cell, the delay controller configured to provide the first, second, third, and fourth voltages, wherein the first, second, third, and fourth voltages are configured such that the first delay is different in duration than the second delay.

2. The circuit of claim 1, further comprising an arbiter circuit coupled to the first delay cell and the second delay cell and configured to receive the delayed first and second signals and to output an arbitration signal indicative of which of the delayed first and second signals is received first by the arbiter circuit.

3. The circuit of claim 1, wherein the first delay cell includes a third inverter circuit coupled to an output terminal of the first inverter circuit, the first delay cell configured to delay the first signal based on the first delay and a third delay of the third inverter circuit, wherein the third delay of the third inverter circuit is based on fifth and sixth voltages provided to fifth and sixth transistors included in the third inverter circuit.

4. The circuit of claim 3, wherein the fifth and sixth voltages are approximately equal to the first and second voltages such that the first delay is approximately equal to the third delay.

5. The circuit of claim 1, wherein the second delay cell includes a third inverter circuit coupled to an output terminal of the second inverter circuit, the second delay cell configured to delay the second signal based on the second delay and a third delay of the third inverter circuit, wherein the third delay of the third inverter circuit is based on fifth and sixth voltages provided to fifth and sixth transistors included in the third inverter circuit.

6. (canceled)

7. The circuit of claim 1, wherein the first and second voltages are complementary such that an increase in the first voltage is accompanied by a decrease in the second voltage.

8. The circuit of claim 7, wherein the second voltage is approximately equal to a supply voltage of the first inverter circuit minus the first voltage.

9. The circuit of claim 7, wherein the increase of the first voltage reduces the first delay of the first inverter circuit.

10. (canceled)

11. (canceled)

12. The circuit of claim 1, wherein the first delay cell includes a capacitor bank of one or more capacitors coupled to an output terminal of the first inverter circuit, the capacitor bank configured to switch one or more capacitors to be electrically coupled to the output terminal of the first inverter circuit based on a control signal.

13. The circuit of claim 1, wherein the digital control signal includes a first digital control signal and the delay controller includes:
a first digital-to-analog converter circuit configured to generate the first voltage and the second voltage based on the first digital control signal; and
a second digital-to-analog converter circuit configured to generate the third and the fourth voltages based on a second digital control signal.

14. (canceled)

15. (canceled)

16. (canceled)

17. (canceled)

18. A circuit, comprising:
a first input terminal configured to receive a first signal;
a second input terminal configured to receive a second signal;
a delay unit coupled to the first and second input terminals, wherein the delay unit includes:
a first delay cell configured to delay the first signal by a first delay based on a first set of voltages applied to a first set of transistors within the first delay cell, the first set of voltages includes a first voltage and a second voltage that are complementary such that an increase in the first voltage is accompanied by a decrease in the second voltage, wherein the first voltage and the second voltage are each independently applied to one transistor of the first set of transistors; and
a second delay cell configured to delay the second signal by a second delay based on a second set of voltages applied to a second set of transistors within the second delay cell;
an arbiter circuit coupled to the delay unit and configured to receive the delayed first and second signals and to output a signal indicative of which of the delayed first and second signals is received first by the arbiter circuit; and
a delay controller coupled to the delay unit, the delay controller configured to provide the first and second sets of voltages to the delay unit, the first and second sets of voltages configured such that the first delay is different in duration than the second delay.

19. (canceled)

20. The circuit of claim 18, wherein the delay controller is configured to adjust the first and second sets of voltages to change the respective first and second delays.

21. (canceled)

22. (canceled)

23. A circuit, comprising:
a digitally controlled oscillator circuit configured to generate an output signal based on a comparison signal;
a digital comparison unit coupled to the digitally controlled oscillator circuit and configured to generate the comparison signal based on the output signal and a reference signal, wherein the digital comparison unit includes a plurality of delay modules, wherein a delay module of the plurality of delay modules includes:
a delay unit configured to receive first and second signals and to output delayed first and second signals, wherein the first signal is delayed by a first delay by a first delay cell based on a first set of voltages that includes a first voltage and a second voltage that is different from the first voltage, wherein the first set of voltages is applied to a first set of transistors within the first delay cell and the second signal is delayed by a second delay by a second delay cell based on a second set of voltages applied to a second set of transistors within the second delay cell; and
an arbiter circuit coupled to the delay unit and configured to output an arbitration signal based on the delayed first and second signals, wherein the comparison signal is based on arbitration signal generated by the delay module.

24. The circuit of claim 23, wherein the delay modules are arranged such that the first signal for the delay unit in a first delay module is the reference signal, wherein the second signal for the delay unit in the first delay module is based on the output signal, and wherein the first and second signals for the delay units in each of the other delay modules are the delayed first and second signals that are output by the delay unit in another of the delay modules.

25. The circuit of claim 23, wherein a resolution of the digital comparison unit is based on a number of the delay modules in the digital comparison unit.

26. The circuit of claim 23, wherein the digital comparison unit further includes a delay controller coupled to the delay modules and configured to provide the first and second sets of voltages to each of the delay modules, the first and second sets of voltages generated by the delay controller based on a delay control signal that indicates the first delay and the second delay for each of the delay modules.

27. (canceled)

28. (canceled)

29. The circuit of claim 23, wherein the first voltage and the second voltage are each independently applied to one transistor of the first set of transistors.

30. The circuit of claim 29, wherein the first voltage and the second voltage are complementary such that an increase in the first voltage is accompanied by a decrease in the second voltage.

31. The circuit of claim 23, further comprising a divider circuit coupled between the digitally controlled oscillator circuit and the digital comparison unit, the divider circuit configured to receive the output signal and to provide a divided output signal, the comparison signal based on a comparison of the divided output signal and the reference signal.

32. A method, comprising:
delaying a first signal in a first delay cell for a first delay, the first delay based on first voltages provided to a first set of transistors in the first delay cell;
delaying a reference signal in a second delay cell for a second delay, the second delay based on second voltages provided to a second set of transistors in the second delay cell;
generating a first arbitration signal based on which of the delayed first signal and the delayed reference signal is respectively output first by the first and second delay cells;
additionally delaying the delayed first signal in a third delay cell for a third delay, the third delay based on third voltages provided to a third set of transistors in the third delay cell;
additionally delaying the delayed reference signal in a fourth delay cell for a fourth delay, the fourth delay based on fourth voltages provided to a fourth set of transistors in the fourth delay cell; and
generating a second arbitration signal based on which of the additionally delayed first signal and the additionally delayed reference signal is respectively output first by the third and fourth delay cells;
generating a comparison signal based on the first arbitration signal and the second arbitration signal; and
generating an output signal based on the comparison signal, wherein the first signal is based on the output signal.

33. (canceled)

34. (canceled)

35. (canceled)

36. The method of claim 32, wherein the first set of voltages in the first cell includes a first voltage and a second voltage, wherein the first voltage and the second voltage are each independently applied to one transistor of the first set of transistors.

37. The method of claim 36, wherein the first voltage and the second voltage are complementary such that an increase in the first voltage is accompanied by a decrease in the second voltage.

38. The method of claim 32, further comprising adjusting the first set of voltages and/or the second set of voltages to respectively adjust the first delay and/or the second delay.
